(19) United States
(12) Patent Application Publication
(10) Pub. No.: US 2025/0338688 A1
(43) Pub. Date: Oct. 30, 2025

(54) LIGHT-EMITTING DEVICE

(71) Applicant: Bridgelux Optoelectronics (Xiamen) Co., Ltd., Xiamen (CN)

(72) Inventors: JINGQIONG ZHANG, Xiamen (CN); JIAZHAI LIN, Xiamen (CN); MANCAI LI, Xiamen (CN); JING CHEN, Xiamen (CN); GUOHENG QIN, Xiamen (CN); DEBING HUANG, Xiamen (CN); CONGLIN WU, Xiamen (CN)

(21) Appl. No.: 19/001,483

(22) Filed: Dec. 25, 2024

(30) Foreign Application Priority Data
Apr. 29, 2024 (CN) 202410532610X

(51) Int. Cl. H10H 29/34

(52) U.S. Cl. CPC H10H 29/34

(57) ABSTRACT

A light-emitting device includes: a first light-emitting unit, a second light-emitting unit and a third light-emitting unit. A chromaticity coordinate x of the first light-emitting unit is 0.65>x>0.49, and a chromaticity point of the first light-emitting unit is below a blackbody radiation curve. A chromaticity coordinate x of the second light-emitting unit is 0.48>x>0.4, and a chromaticity point of the second light-emitting unit is above the blackbody radiation curve. A third light-emitting unit, wherein a chromaticity coordinate x of the third light-emitting unit is 0.31>x>0.22, and a chromaticity point of the third light-emitting unit is above the blackbody radiation curve. The CIExy of the light-emitting device conforms to the blackbody radiation curve during a tuning process.

### CROSS-REFERENCE TO RELATED APPLICATION

This application claims priority to Chinese Patent Application No. 202410532610.X, filed Apr. 29, 2024, which is herein incorporated by reference in its entirety.

### TECHNICAL FIELD

The disclosure relates to the field of lighting technologies, and more particularly to a light-emitting device capable of achieving full-spectrum white light tuning.

### BACKGROUND

Human life cannot be separated from lighting, and a most basic element of the lighting is a light source. Especially with the development of lighting technology, common lighting sources have evolved from incandescent lamps and fluorescent lamps in an early stage to light-emitting diode (LED) lights which are more widely used in recent years. Based on the development of LED lighting technology, the need for correlated color temperature (CCT) tuning of high color rendering index (CRI) LED lights has become an important direction. Referring to FIG. 1, a solution for CCT tuning is through adjusting a current ratio of a warm white light source and a cool white light source. However, the CIExy (refers to the Commission Internationale de l'Éclairage 1931 xy chromaticity space) of intermediate color temperature lights deviates significantly from a blackbody radiation curve (BBC, also referred to as blackbody radiation locus). For conventional light sources with a CRI 80, since a R9 value of the light source is relatively low, red saturation is insufficient, and thus CRI values of the intermediate color temperature lights that deviate from the blackbody radiation curve are not significantly affected. However, for light sources with a R9 value greater than 90, such as full-spectrum white light sources, since the red saturation of the basic monochromatic temperature light source is already very high, using this tuning method will cause the intermediate color temperature lights to deviate from the blackbody radiation curve due to the over-saturation of red, leading to a lower CRI value for the intermediate color temperature lights, which cannot meet requirements of full-spectrum white light. Therefore, there is an urgent need for a light-emitting product that can achieve full-spectrum white light tuning, to address the need for its CIExy coordinates to fit the blackbody radiation curve during a full-spectrum white light tuning process.

### SUMMARY

To overcome above shortcomings and problems, an embodiment of the disclosure provides a light-emitting device.

In an aspect, the embodiment of the disclosure provides a light-emitting device, which includes: a first light-emitting unit, a second light-emitting unit and a third light-emitting unit. A chromaticity coordinate x of the first light-emitting unit is 0.65>x>0.49, and a chromaticity point of the first light-emitting unit is located below a blackbody radiation curve. A chromaticity coordinate x of the second light-emitting unit is 0.48>x>0.4, and a chromaticity point of the second light-emitting unit is located above the blackbody radiation curve. A chromaticity coordinate x of the third light-emitting unit is 0.31>x>0.22, and a chromaticity point of the third light-emitting unit is located above the blackbody radiation curve.

In another aspect, the embodiment of the disclosure further provides a light-emitting device, including: a first light-emitting unit, a second light-emitting unit and a third light-emitting unit; and a peak wavelength of light emitted by the first light-emitting unit is in a range of 632 nanometers (nm) to 642 nm, a peak wavelength of light emitted by the second light-emitting unit is in a range of 624 nm to 636 nm, and a peak wavelength of light emitted by the third light-emitting unit is in a range of 430 nm to 480 nm.

It can be seen that the embodiment of the disclosure achieves full-spectrum white light tuning from 2700 to 6500 Kelvins (K) with a smaller color gamut by selecting at least three specific light-emitting units, thereby allowing the light-emitting device to have higher brightness and better luminous efficiency, and the CIExy coordinates of the light-emitting device fit the blackbody radiation curve during a tuning process.

### BRIEF DESCRIPTION OF DRAWINGS

In order to describe technical solutions of embodiments of the disclosure clearly, the accompanying drawings required for the description of the embodiments are briefly introduced below. It is apparent that the accompanying drawings described below are only some of the embodiments of the disclosure. For those skilled in the art, other drawings can be obtained based on these accompanying drawings without creative labor.

FIG. 1 illustrates a schematic comparison diagram of a blackbody radiation curve and a tuning trajectory in the related art.

FIG. 2 illustrates a schematic structural diagram of a light-emitting device according to an embodiment of the disclosure.

FIG. 3 illustrates a chromaticity coordinate diagram of the light-emitting device in FIG. 2.

FIG. 4 illustrates a schematic spectrum diagram of the light-emitting device in FIG. 2.

FIG. 5A and FIG. 5B illustrate schematic spectrum diagrams of white light synthesized by the light-emitting device in FIG. 2 at different color temperatures.

FIG. 6A illustrates a schematic structural diagram of a leadframe of a light-emitting device according to an embodiment of the disclosure.

FIG. 6B illustrates a first schematic structural diagram of the light-emitting device according to the embodiment of the disclosure.

FIG. 7 illustrates a second schematic structural diagram of the light-emitting device according to the embodiment of the disclosure.

FIG. 8 illustrates a third schematic structural diagram of the light-emitting device according to the embodiment of the disclosure.

FIG. 9 illustrates a fourth schematic structural diagram of the light-emitting device according to the embodiment of the disclosure.

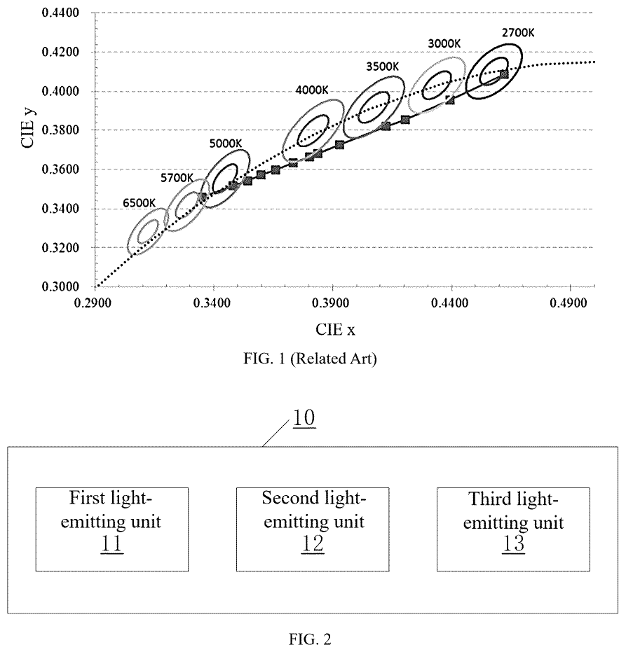

### DETAILED DESCRIPTION OF EMBODIMENTS

In order to clarify the purpose, technical solutions, and advantages of embodiments of the disclosure, a clear and complete description of the technical solutions in the embodiments of the disclosure is provided below in conjunction with the accompanying drawings. Apparently, the described embodiments are only a part of the embodiments of the disclosure, not all of them. Based on the embodiments described in the disclosure, all other embodiments obtained by those skilled in the art without creative labor are within the scope of protection of the disclosure.

In the embodiments of the disclosure, descriptions related to “first” and “second” etc., are only for descriptive purposes and cannot be understood as indicating or implying their relative importance or implying the number of technical features indicated. Therefore, the features that are limited to “first” and “second” can explicitly or implicitly include at least one of the features.

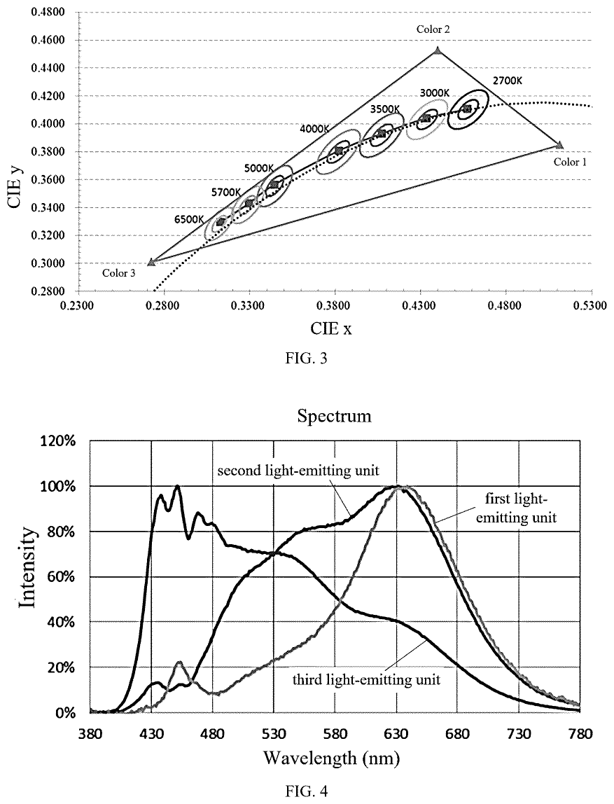

Referring to FIG. 2 and FIG. 3, an embodiment of the disclosure provides a light-emitting device 10, for example, including: a first light-emitting unit 11, a second light-emitting unit 12 and a third light-emitting unit 13. A chromaticity coordinate x of the first light-emitting unit 11 is 0.65>x>0.49, and a chromaticity point of the first light-emitting unit 11 is located below a blackbody radiation curve. A chromaticity coordinate x of the second light-emitting unit 12 is 0.48>x>0.4, and a chromaticity point of the second light-emitting unit 12 is located above the blackbody radiation curve. A chromaticity coordinate x of the third light-emitting unit 13 is 0.31>x>0.22, and a chromaticity point of the third light-emitting unit 13 is located above the blackbody radiation curve.

The chromaticity point of the first light-emitting unit 11 is located below the blackbody radiation curve, the chromaticity point of the second light-emitting unit 12 is located above the blackbody radiation curve, and the chromaticity point of the third light-emitting unit 13 is located above the blackbody radiation curve. The chromaticity coordinate x of the first light-emitting unit 11 is set as 0.65>x>0.49, the chromaticity coordinate x of the second light-emitting unit 12 is set as 0.48>x>0.4, and the chromaticity coordinate x of the third light-emitting unit 13 is set as 0.31>x>0.22. Brightness of light emitted by the light-emitting device 10 is higher, the closer it is to a peak value of a photopic luminous efficiency function at 555 nanometers (nm). Taking the third light-emitting unit 13 as an example, under a premise of covering all CCT, the larger the chromaticity coordinate x, the higher the brightness. Taking the first light-emitting unit 11 as an example, the lower the chromaticity point, the more the proportion of red light, and the lower the brightness. The higher the chromaticity coordinate y of the second light-emitting unit 12, the brightness of the second light-emitting unit 12 is higher, however, the higher the chromaticity coordinate y of the second light-emitting unit 12, the smaller the current proportion of the second light-emitting unit 12 in mixed light, which leads to an increase in a current of the first light-emitting unit 11 and a decrease of the overall brightness. Therefore, referring to FIG. 3, the light-emitting device 10 provided by the embodiment makes an area of a color gamut enclosed by the three light-emitting units smaller within a same CCT range, the brightness of the mixed light can be improved, making luminous efficiency of the light-emitting device 10 also better.

Furthermore, in an implementation method of the embodiment, a distance between the chromaticity point of the first light-emitting unit 11 and the chromaticity point of the second light-emitting unit 12 is in a range of 0.09 to 0.14, a distance between the chromaticity point of the second light-emitting unit 12 and the chromaticity point of the third light-emitting unit 13 is in a range of 0.19 to 0.24, and a distance between the chromaticity point of the first light-emitting unit 11 and the chromaticity point of the third light-emitting unit 13 is in a range of 0.24 to 0.28. By limiting the distance between the chromaticity points of the first light-emitting unit 11, the second light-emitting unit 12 and the third light-emitting unit 13, the area of the color gamut enclosed by the first light-emitting unit 11, the second light-emitting unit 12, and the third light-emitting unit 13 is further defined.

In another implementation method of the embodiment, a chromaticity coordinate y of the first light-emitting unit 11 is in a range of 0.33 to 0.415, a chromaticity coordinate y of the second light-emitting unit 12 is in a range of 0.4 to 0.52, and a chromaticity coordinate y of the third light-emitting unit 13 is in a range of 0.25 to 0.38. By limiting the range of the chromaticity coordinates x and y of the first light-emitting unit 11, the second light-emitting unit 12 and the third light-emitting unit 13, the area of the color gamut enclosed by the first light-emitting unit 11, the second light-emitting unit 12, and the third light-emitting unit 13 is further defined, allowing the light-emitting device 10 to cover the same CCT range with a smaller area of the color gamut enclosed by the three light-emitting units, thereby achieving better luminous efficiency of the light-emitting device 10.

Furthermore, referring to FIG. 4, in the light-emitting device 10 provided by the embodiment, a peak wavelength of light emitted by the first light-emitting unit 11 is larger than a peak wavelength of light emitted by the second light-emitting unit 12, and a peak wavelength of light emitted by the second light-emitting unit 12 is larger than a peak wavelength of light emitted by the third light-emitting unit 13. Specifically, the peak wavelength of the light emitted by the first light-emitting unit 11, for example, can be in a range of 632 nm to 642 nm, the peak wavelength of the light emitted by the second light-emitting unit 12, for example, can be in a range of 624 nm to 636 nm, and the peak wavelength of the light emitted by the third light-emitting unit 13, for example, can be in a range of 430 nm to 480 nm, which allow the light-emitting device 10, while covering the same CCT range, to have the smaller area of the color gamut enclosed by the three light-emitting units. As a result, the luminous efficiency of the light-emitting device 10 can be better. By selecting the peak wavelengths of the three light-emitting units, an entire tuning result can be more in line with the standard light source (full-spectrum white light) within a visible light range recognizable by the human eye.

In the light-emitting device 10 provided by the embodiment, in order to achieve a tuning result that meets requirements of the full-spectrum white light (CRI greater than 95, Rf greater than 95, R1 to R15 all greater than 90), a full width at half maximum (FWHM) of the light emitted by the first light-emitting unit 11 is greater than 95 nm, a FWHM of the light emitted by the second light-emitting unit 12 is greater than 180 nm, and a FWHM of the light emitted by the third light-emitting unit 13 is greater than 150 nm. In order to make the tuning result more closely match a spectral curve of the standard light source at a corresponding CCT, it is possible to select a full width at 70% intensity of the light emitted by the first light-emitting unit 11 to be greater than 65 nm, a full width at 70% intensity of the light emitted by the second light-emitting unit 12 to be greater than 135 nm, and a full width at 70% intensity of the light emitted by the third light-emitting unit 13 to be greater than 115 nm.

In an implementation of the embodiment, the first light-emitting unit 11 may exemplarily include a first light-emitting chip 111, the second light-emitting unit 12 may exemplarily include a second light-emitting chip 121, and the third light-emitting unit 13 may exemplarily include a third light-emitting chip 131. In a specific implementation method of the embodiment, the third light-emitting chip 131 uses a broad-wavelength blue light chip (i.e., a blue light chip with FWHM greater than 25 nm) which may have multiple peaks (or peak inflection points). For example, at a current density of 120 milliamperes per square millimeter (mA/mm²), a wavelength of a main peak of the broad-wavelength blue light chip used in the embodiment is in a range of 430 nm to 445 nm, i.e., the third light-emitting unit 13 of the embodiment uses a broad-wavelength blue light chip that has a first peak within the range of 430 nm to 445 nm. The first light-emitting chip 111 and the second light-emitting chip 121 may use the same broad-wavelength blue light chips, or use conventional narrow-wavelength blue light chips, i.e., blue light chips with FWHM less than 20 nm and a single peak. In a specific implementation, a dominant wavelength of each of the first light-emitting chip 111 and the second light-emitting chip 121 is in a range of 445 nm to 470 nm. In a preferred implementation, the dominant wavelengths of the first light-emitting chip 111 and the second light-emitting chip 121 can differ by 9 nm or more, which can make the light-emitting device 10 closer to the full-spectrum white light in a blue light part.

In an implementation of the embodiment, the first light-emitting unit 11 may include a first light-emitting chip 111, the second light-emitting unit 12 may include a second light-emitting chip 121, and the third light-emitting unit 13 may include a fourth light-emitting chip and a fifth light-emitting chip. The first light-emitting chip 111 and the second light-emitting chip 121 can use either the broad-wavelength blue light chips or the narrow-wavelength blue light chips as previously described. The fourth light-emitting chip and the fifth light-emitting chip can use narrow-wavelength blue light chips with different dominant wavelengths, which are mixed to form broad-wavelength blue light. For example, a dominant wavelength range of the fourth light-emitting chip is in the range of 435 nm to 460 nm, and a dominant wavelength range of the fifth light-emitting chip can be in the range of 460 nm to 470 nm.

Furthermore, the light-emitting device 10 may include the first light-emitting unit 11, the second light-emitting unit 12 and two third light-emitting units 13. The two third light-emitting units 13 can be set to achieve an adjustment process in which a maximum current used by each light-emitting unit is as close as possible, allowing power of the light-emitting device 10 to be larger. In an implementation of the embodiment, the two third light-emitting units 13 are the same, both using the broad-wavelength blue light chips. In an implementation of the embodiment, the two third light-emitting units 13 can be different, for example, they can respectively use the fourth light-emitting chip and the fifth light-emitting chip described above.

Furthermore, the light-emitting unit may exemplarily include a light-emitting chip and a wavelength conversion medium, and the wavelength conversion medium may exemplarily cover on the light-emitting chip. The light-emitting chip may exemplarily use the LED blue light chip, and the wavelength conversion medium may exemplarily use a phosphor. The first light-emitting unit 11, the second light-emitting unit 12, and the third light-emitting unit 13 may specifically use the same phosphor with different proportions or use different phosphors. Of course, the embodiment is not limited to this. Specifically, in an implementation of the embodiment, the first light-emitting unit 11 may include a first red phosphor and a first yellow-green phosphor, the second light-emitting unit 12 may include a second red phosphor and a second yellow-green phosphor, the third light-emitting unit 13 may include a third red phosphor and a third yellow-green phosphor. The first red phosphor, the second red phosphor and the third red phosphor may be one selected from the group consisting of SCASN ((Sr,Ca)AlSiN₃:Eu²⁺), CASN (CaAlSiN₃) and BSSN (BaSi₂SN_{2.67}). The first yellow-green phosphor, the second yellow-green phosphor and the third yellow-green phosphor may be one selected from the group consisting of LuAG (Lu₃Al₅O₁₂:Ce³⁺), LuYAG, GaYAG (Ga₃Al₅O₁₂) and YAG (Y₃Al₅O₁₂). A content of the first red phosphor is larger than a content of the second red phosphor, and the content of the second red phosphor is larger than a content of the third red phosphor. In a specific implementation of the embodiment, a weight of the first red phosphor is 3-8 times a weight of the second red phosphor, the weight of the first red phosphor is more than 5 times a weight of the third red phosphor. Referring to Table 1, for example, in the first light-emitting unit 11, a proportion of the first red phosphor can, for example, be greater than 20%, and a proportion of the first yellow-green phosphor can, for example, be less than 80%; in the second light-emitting unit 12, a proportion of the second red phosphor can for example be less than 10%, and a proportion of the second yellow-green phosphor can for example be greater than 90%; and in the third light-emitting unit 13, a proportion of the third red phosphor can for example be greater than 2%, and a proportion of the third yellow-green phosphor can for example be less than 98%.

TABLE 1

| | Yellow-green phosphor | Red phosphor |
|---|---|---|
| Phosphor material | LuAG, LuYAG, GaYAG, | SCASN/CASN/BSSN |
| | YAG | |
| First light-emitting unit | <80% | >20% |
| Second light-emitting unit | >90% | <10% |
| Third light-emitting unit | <98% | >2% |

Referring to FIG. 4, by selecting the phosphors, a ratio between a maximum intensity in a range of 500 nm to 550 nm and a maximum intensity in a range of 400 nm to 480 nm of a spectrum generated by exciting the third yellow-green phosphor and the third red phosphor by the third light-emitting unit 13 can be achieved to be in a range of 60% to 80%. Meanwhile, a ratio between a maximum intensity in the range of 500 nm to 550 nm and a maximum intensity in the range of 400 nm to 480 nm for both the first light-emitting unit 11 and the second light-emitting unit 12 is less than 25%. In this way, a blue light band in a white light spectrum synthesized by the light-emitting device 10 can be mainly contributed by the third light-emitting unit 13, while a proportion of blue light from the first light-emitting unit 11 and the second light-emitting unit 12 is kept as low as possible, thereby better achieving a low CCT (e.g., 2700 K).

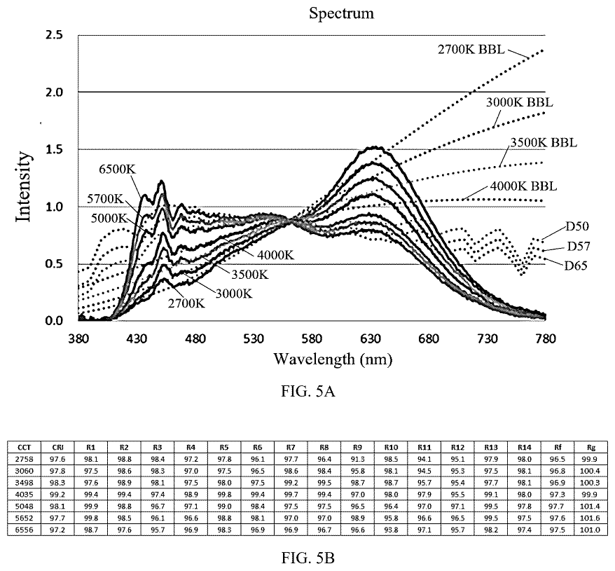

Referring to FIG. 5A and FIG. 5B, a mixing effect of the light-emitting device 10 provided in this embodiment achieves a CRI and Rf both over 95, and R1 to R14 over 90 within a range of 2700 K to 6500 K, and the CIExy of the light-emitting device 10 can be adjusted along the blackbody radiation curve (i.e., the spectrum is within a human eye's recognizable range of 425-690 nm, closer to the standard light source curve). Taking the light-emitting device 10 provided in this embodiment as an example, which includes the first light-emitting unit 11, the second light-emitting unit 12, and the two third light-emitting units 13/13′ (i.e., the third light-emitting unit 13 and another third light-emitting units 13′), a current ratio of the two third light-emitting units 13/13′ increases with an increase of the CCT, a current ratio of the second light-emitting unit 12 first increases and then decreases with the increase of the CCT, and a current ratio of the first light-emitting unit 11 decreases with the increase of the CCT. Referring to Table 2, a sum of the current ratios of the first light-emitting unit 11, the second light-emitting unit 12, and the two third light-emitting units 13/13′ is 100%, and the current ratios of the two third light-emitting units 13/13′ can, for example, be the same. When the CCT is 2700 K, the current ratio of the first light-emitting unit 11 can be, for example, 50%; when the CCT is 3000 K, the current ratio of the first light-emitting unit 11 can be, for example, 39.9%, and when the CCT is 3500 K, the current ratio of the first light-emitting unit 11 can be, for example, 29.9%, that is, the current ratio of the first light-emitting unit 11 decreases with the increase of the CCT. When the CCT is 2700 K, the current ratio of the second light-emitting unit 12 can be, for example, 44.8%, when the CCT is 3000 K, the current ratio of the second light-emitting unit 12 can be, for example, 48.6%, when the CCT is 3500 K, the current ratio of the second light-emitting unit 12 can be, for example, 49.4%, when the CCT is 4000 K, the current ratio of the second light-emitting unit 12 can be, for example, 49.0%, and when the CCT is 5000 K, the current ratio of the second light-emitting unit 12 can be, for example, 32.3%, that is, the current ratio of the second light-emitting unit 12 first increases and then decreases with the increase of the CCT. When the CCT is 2700 K, the current ratio of the two third light-emitting units 13/13′ can be, for example, 2.6%, when the CCT is 3000 K, the current ratio of the two third light-emitting units 13/13′ can be, for example, 5.8%, when the CCT is 3500 K, the current ratio of the two third light-emitting units 13/13′ can be, for example, 10.3%, that is, the current ratio of the two third light-emitting units 13/13′ increases with the increase of the CCT.

TABLE 2

| | Current ratio | | | |
|---|---|---|---|---|
| | Third light- | Third light- | Second light- | First light-emitting |
| CCT | emitting unit | emitting unit | emitting unit | unit |
| 2700K | 2.6% | 2.6% | 44.8% | 50.0% |
| 3000K | 5.8% | 5.8% | 48.6% | 39.9% |
| 3500K | 10.3% | 10.3% | 49.4% | 29.9% |
| 4000K | 15.6% | 15.6% | 49.0% | 19.7% |
| 5000K | 26.4% | 26.4% | 32.3% | 14.9% |
| 5700K | 32.0% | 32.0% | 21.1% | 14.8% |
| 6500K | 38.3% | 38.3% | 9.2% | 14.3% |

The light-emitting device 10 provided in the embodiment of the disclosure is shown in FIG. 2. The first light-emitting unit 11 may exemplarily include the first light-emitting chip 111 and a first encapsulant 101 covering the first light-emitting chip 111, the second light-emitting unit 12 may exemplarily include the second light-emitting chip 121 and a second encapsulant 102 covering the second light-emitting chip 121, and the third light-emitting unit 13 may exemplarily include a third encapsulant 103 covering the third light-emitting chip 131.

Specifically, for example, the structure of the light-emitting device 10 provided in the embodiment of the disclosure can include a leadframe 20 and an encapsulant. The leadframe 20 may exemplarily define a first accommodation slot, a second accommodation slot, and a third accommodation slot, that is, the leadframe 20 can define three accommodation slots, which can also be called bowls. The first light-emitting unit 11 can be disposed in the first accommodation slot, the second light-emitting unit 12 is disposed in the second accommodation slot, and the third light-emitting unit 13 is disposed in the third accommodation slot.

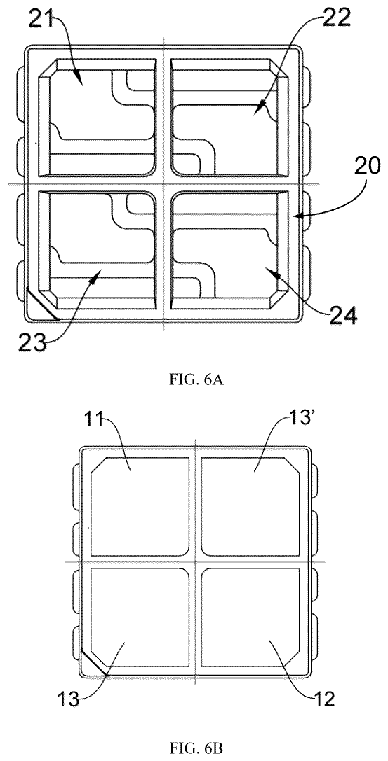

Furthermore, referring to FIG. 6A and FIG. 6B, the light-emitting device 10 includes the first light-emitting unit 11, the second light-emitting unit 12, the third light-emitting unit 13 and the another third light-emitting units 13′. The leadframe 20 defines the first accommodation slot 21, the second accommodation slot 22, the third accommodation slot 23 and a fourth accommodation slot 24. The first light-emitting unit 11 is disposed in the first accommodation slot 21, the second light-emitting unit 12 is disposed in the second accommodation slot 22, the third light-emitting unit 13 is disposed in the third accommodation slot 23, and the another third light-emitting units 13′ is disposed in the fourth accommodation slot 24. The second accommodation slot 22 and the fourth accommodation slot 24 can be disposed diagonally, i.e., the third light-emitting unit 13 and the another third light-emitting unit 13′ are disposed diagonally, making the mixing effect better.

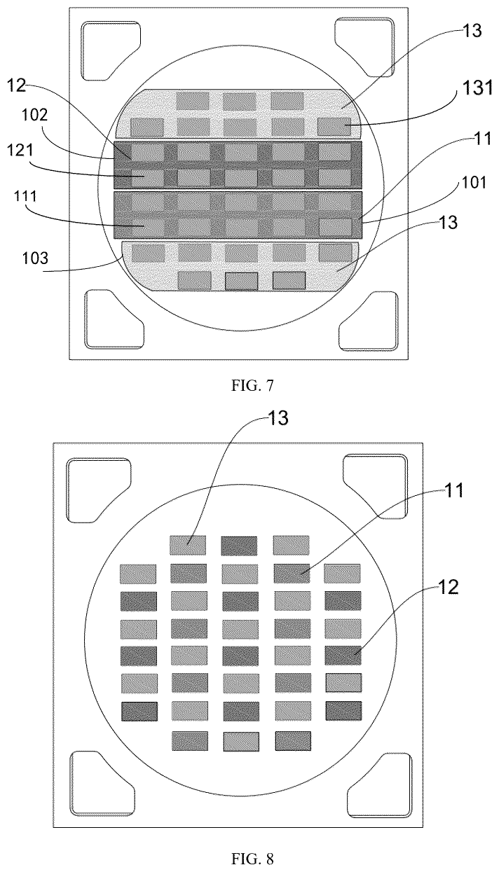

A second specific structure of the light-emitting device 10 provided in the embodiment of the disclosure is shown in FIG. 7. A chip on board (COB) substrate can be provided with multiple first light-emitting chips 111, multiple second light-emitting chips 121, and multiple third light-emitting chips 131. The multiple first light-emitting chips 111 are covered with first phosphor gel to form the first light-emitting unit 11, the multiple second light-emitting chips 121 are covered with second phosphor gel to form the second light-emitting unit 12, and the multiple third light-emitting chips 131 are covered with third phosphor gel to form the third light-emitting unit 13.

A third specific structure of the light-emitting device 10 provided by the embodiment of the disclosure is shown in FIG. 8. A substrate is provided with the first light-emitting unit 11, the second light-emitting unit 12, and the third light-emitting unit 13 which are packaged with multiple chip-scale packages (CSP). The first light-emitting unit 11, the second light-emitting unit 12, and the third light-emitting unit 13 are preferably arranged in a checkerboard-like staggered pattern.

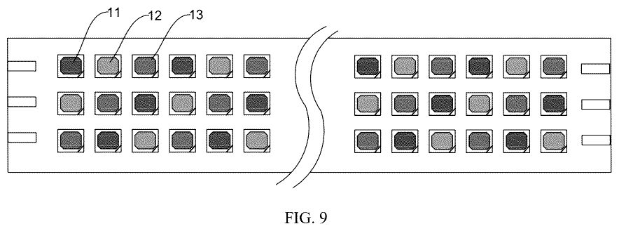

A fourth specific structure of the light-emitting device 10 provided by the embodiment of the disclosure is shown in FIG. 9. Multiple first light-emitting units 11, second light-emitting units 12, and third light-emitting units 13 can be surface-mounted devices (i.e., SMD), such as lamp beads. They are arranged in an alternate or staggered manner on a substrate to form the light-emitting device 10 which is a full-spectrum white light lamp panel or strip-type light-emitting device. Of course, the above are only for illustrative purposes, and the embodiment is not limited to this.

In summary, in the embodiment of the disclosure, the light-emitting device 10 includes at least three different types of light-emitting units. By specifically selecting the chromaticity points, peak wavelengths, or FWHM of the light-emitting units, the light-emitting device 10 of this embodiment achieves the CIExy conforming to the blackbody radiation curve during tuning, meeting color tolerance requirements of 4step. The overall tuning result is more consistent with the standard light source (full-spectrum white light) within the visible light range recognizable by the human eye.

Finally, it should be noted that the above embodiments are only used to illustrate the technical solutions of the disclosure, and not to limit it. Although the disclosure is described in detail with reference to the embodiments, those skilled in the art should understand that they can still modify the technical solutions described in the embodiments, or equivalently replace some of the technical features. These modifications or substitutions do not depart from the essence and scope of the corresponding technical solutions of the embodiments of the disclosure.

What is claimed is:

1. A light-emitting device, comprising:
a first light-emitting unit, wherein a chromaticity coordinate x of the first light-emitting unit is 0.65>x>0.49, and a chromaticity point of the first light-emitting unit is located below a blackbody radiation curve;
a second light-emitting unit, wherein a chromaticity coordinate x of the second light-emitting unit is 0.48>x>0.4, and a chromaticity point of the second light-emitting unit is located above the blackbody radiation curve; and
a third light-emitting unit, wherein a chromaticity coordinate x of the third light-emitting unit is 0.31>x>0.22, and a chromaticity point of the third light-emitting unit is located above the blackbody radiation curve.

2. The light-emitting device as claimed in claim 1, wherein a distance between the chromaticity point of the first light-emitting unit and the chromaticity point of the second light-emitting unit is in a range of 0.09 to 0.14, a distance between the chromaticity point of the second light-emitting unit and the chromaticity point of the third light-emitting unit is in a range of 0.19 to 0.24, and a distance between the chromaticity point of the first light-emitting unit and the chromaticity point of the third light-emitting unit is in a range of 0.24 to 0.28.

3. The light-emitting device as claimed in claim 1, wherein a chromaticity coordinate y of the first light-emitting unit is in a range of 0.33 to 0.415, a chromaticity coordinate y of the second light-emitting unit is in a range of 0.4 to 0.52, and a chromaticity coordinate y of the third light-emitting unit is in a range of 0.25 to 0.38.

4. The light-emitting device as claimed in claim 1, wherein a peak wavelength of light emitted by the first light-emitting unit is in a range of 632 nm to 642 nm, a peak wavelength of light emitted by the second light-emitting unit is in a range of 624 nm to 636 nm, and a peak wavelength of light emitted by the third light-emitting unit is in a range of 430 nm to 480 nm.

5. The light-emitting device as claimed in claim 1, wherein a full width at half-maximum (FWHM) of the light emitted by the first light-emitting unit is greater than 95 nm, a FWHM of the light emitted by the second light-emitting unit is greater than 180 nm, and a FWHM of the light emitted by the third light-emitting unit is greater than 150 nm.

6. The light-emitting device as claimed in claim 1, wherein the third light-emitting unit comprises a light-emitting chip, a FWHM of the light-emitting chip is greater than 25 nm, and the light-emitting chip has a first peak value in a range of 430 nm to 445 nm.

7. The light-emitting device as claimed in claim 1, wherein the third light-emitting unit comprises two light-emitting chips, a dominant wavelength of one of the two light-emitting chips is in a range of 435 nm to 460 nm, and a dominant wavelength of the other one of the two light-emitting chips is in a range of 460 nm to 470 nm.

8. The light-emitting device as claimed in claim 6, wherein the first light-emitting unit comprises a first red phosphor and a first yellow-green phosphor, the second light-emitting unit comprises a second red phosphor and a second yellow-green phosphor, the third light-emitting unit further comprises a third red phosphor and a third yellow-green phosphor, a content of the first red phosphor is larger than a content of the second red phosphor, and the content of the second red phosphor is larger than a content of the third red phosphor.

9. The light-emitting device as claimed in claim 7, wherein the first light-emitting unit comprises a first red phosphor and a first yellow-green phosphor, the second light-emitting unit comprises a second red phosphor and a second yellow-green phosphor, the third light-emitting unit further comprises a third red phosphor and a third yellow-green phosphor, a content of the first red phosphor is larger than a content of the second red phosphor, and the content of the second red phosphor is larger than a content of the third red phosphor.

10. The light-emitting device as claimed in claim 6, wherein the first light-emitting unit comprises a first light-emitting chip and a first encapsulant covering the first light-emitting chip, the second light-emitting unit comprises a second light-emitting chip and a second encapsulant covering the second light-emitting chip, and the third light-emitting unit further comprises a third encapsulant covering the light-emitting chip of the third light-emitting unit.

11. The light-emitting device as claimed in claim 7, wherein the first light-emitting unit comprises a first light-emitting chip and a first encapsulant covering the first light-emitting chip, the second light-emitting unit comprises a second light-emitting chip and a second encapsulant covering the second light-emitting chip, and the third light-emitting unit further comprises a third encapsulant covering the two light-emitting chips of the third light-emitting unit.

12. The light-emitting device as claimed in claim 6, further comprising: a leadframe, wherein the leadframe defines a first accommodation slot, a second accommodation slot and a third accommodation slot, the first light-emitting unit is disposed in the first accommodation slot, the second light-emitting unit is disposed in the second accommodation slot, and the third light-emitting unit is disposed in the third accommodation slot.

13. The light-emitting device as claimed in claim 7, further comprising: a leadframe, wherein the leadframe defines a first accommodation slot, a second accommodation slot and a third accommodation slot, the first light-emitting unit is disposed in the first accommodation slot, the second light-emitting unit is disposed in the second accommodation slot, and the third light-emitting unit is disposed in the third accommodation slot.

14. The light-emitting device as claimed in claim 12, wherein the leadframe further defines a fourth accommodation slot provided with another third light-emitting unit therein.

15. The light-emitting device as claimed in claim 13, wherein the leadframe further defines a fourth accommodation slot provided with another third light-emitting unit therein.

16. The light-emitting device as claimed in claim 6, wherein the first light-emitting unit, the second light-emitting unit and the third light-emitting unit are chip-scale packaged.

17. The light-emitting device as claimed in claim 7, wherein the first light-emitting unit, the second light-emitting unit and the third light-emitting unit are chip-scale packaged.

18. A light-emitting device, comprising:
a first light-emitting unit, wherein a peak wavelength of light emitted by the first light-emitting unit is in a range of 632 nm to 642 nm;
a second light-emitting unit, wherein a peak wavelength of light emitted by the second light-emitting unit is in a range of 624 nm to 636 nm; and
a third light-emitting unit, wherein a peak wavelength of light emitted by the third light-emitting unit is in a range of 430 nm to 480 nm.

19. The light-emitting device as claimed in claim 18, wherein a FWHM of the light emitted by the first light-emitting unit is greater than 95 nm, a FWHM of the light emitted by the second light-emitting unit is greater than 180 nm, and a FWHM of the light emitted by the third light-emitting unit is greater than 150 nm.

20. The light-emitting device as claimed in claim 18, wherein a full width at 70% intensity of the light emitted by the first light-emitting unit is greater than 65 nm, a full width at 70% intensity of the light emitted by the second light-emitting unit is greater than 135 nm, and a full width at 70% intensity of the light emitted by the third light-emitting unit is greater than 115 nm.
